(19) United States
(12) Patent Application Publication
(10) Pub. No.: US 2026/0026334 A1
(43) Pub. Date: Jan. 22, 2026

(54) SEMICONDUCTOR DEVICE AND METHOD OF MANUFACTURING THE SAME

(71) Applicant: Renesas Electronics Corporation, Tokyo (JP)

(72) Inventor: Tomokazu MATSUZAKI, Tokyo (JP)

(21) Appl. No.: 19/250,458

(22) Filed: Jun. 26, 2025

(30) Foreign Application Priority Data
Jul. 17, 2024 (JP) 2024-114217

(51) Int. Cl. H01L 23/00; H01L 23/31; H01L 23/528

(52) U.S. Cl. CPC H01L 24/48; H01L 23/3114; H01L 23/5286; H01L 24/06; H01L 2224/04042; H01L 2224/06152; H01L 2224/4813; H01L 2224/48245; H01L 2924/1431; H01L 2924/1434; H01L 2924/30205

(57) ABSTRACT

A semiconductor device includes a plurality of bonding pads which are constituted by an uppermost layer of a wiring layers, first and third bonding pads connected to an external power supply of the semiconductor chip, second and fourth bonding pads connected to the ground, a fifth bonding pad connected to the third bonding pad via the first inner wiring, and a sixth bonding pad connected to the fourth bonding pad via the second inner wiring, wherein there is no wiring constituting a circuit in one layer just below the uppermost layer at the first and second bonding pads, and there is a wiring constituting the circuit in the one layer just below the uppermost layer at the third to sixth bonding pads.

### CROSS-REFERENCE TO RELATED APPLICATIONS

The disclosure of Japanese Patent Application No. 2024-114217 filed on Jul. 17, 2024, including the specification, drawings and abstract is incorporated herein by reference in its entirety.

### BACKGROUND

The present disclosure relates to a semiconductor device and a method of manufacturing a semiconductor device, and more particularly, to a semiconductor device including a plurality of bonding pads and a method of manufacturing the semiconductor device.

A semiconductor device including a semiconductor chip has an electrode pad for connection with an electrode terminal provided outside, and a wire bonding technique may be used for connection between the external electrode terminal and the electrode pad.

For example, Patent Literature 1 discloses a semiconductor device in which a power supply pad for supplying power to a semiconductor chip is arranged in a grid pattern, and the power supply pads are wire-bonded to each other.

### PRIOR ART DOCUMENT

### Patent Document

[Patent Document 1] Japanese Unexamined Publication laid-open No. 2005-085829

### SUMMARY

In a semiconductor chip, for example, a logic circuit or the like is required to be highly integrated, and in order to reduce a L/S ratio (a ratio between a wiring width and a wiring distance), a metal layer serving as a wiring needs to be thinned.

On the other hand, in I/O circuitry (input/output circuitry) and the like, in order to improve I/O capability and ESD resistance (Electro-Static Discharge: electrostatic discharging), it is preferable to lower the impedance of the metal layer serving as the wiring, and it is preferable that the thickness of the metal layer serving as the wiring is larger.

Therefore, it can be said that there is room for further study in order to provide a plurality of circuits in the semiconductor chip. Other problems and novel features will be apparent from the description of the present specification and the accompanying drawings.

According to an embodiment, semiconductor device includes a semiconductor chip comprising: a substrate; a first circuit region on the substrate; a second circuit region disposed on the substrate and surrounding the first circuit region in a plan view of the semiconductor device; and a plurality of bonding pads, wherein the substrate includes a plurality of wiring layers, wherein the first circuit region is provided with a first circuit constituted by the wiring layers, wherein the second circuit region is provided with a second circuit constituted by the wiring layers, wherein the plurality of bonding pads is formed in the second circuit region, and is constituted by an uppermost layer of the wiring layers, wherein the plurality of bonding pads comprises: a first bonding pad and a third bonding pad connected to a power supply outside the semiconductor chip; a second bonding pad and a fourth bonding pad connected to a ground; a fifth bonding pad connected to the third bonding pad via a first inner wiring; and a sixth bonding pad connected to the fourth bonding pad via a second inner wiring, wherein, in a cross-sectional view of the semiconductor device, there is no wiring constituting the second circuit in one layer just below the uppermost layer of the wiring layers in regions where the first bonding pad and the second bonding pad are formed, and wherein, in a cross-sectional view of the semiconductor device, there is a wiring constituting the second circuit in one layer just below the uppermost layer of the wiring layers in regions where the third to sixth bonding pad are formed.

According to an embodiment, a method of manufacturing a semiconductor device includes providing a semiconductor chip, wherein the semiconductor chip comprises: a substrate; a first circuit region on the substrate; a second circuit region disposed on the substrate and surrounding the first circuit region in a plan view of the semiconductor device; and a plurality of bonding pads, wherein the substrate includes a plurality of wiring layers, wherein the first circuit region is provided with a first circuit constituted by the wiring layers, wherein the second circuit region is provided with a second circuit constituted by the wiring layers, wherein the plurality of bonding pads is formed in the second circuit region, and is constituted by an uppermost layer of the wiring layers, wherein the plurality of bonding pads comprises: a first bonding pad and a third bonding pad connected to a power supply outside the semiconductor chip; a second bonding pad and a fourth bonding pad connected to a ground; a fifth bonding pad connected to the third bonding pad; and a sixth bonding pad connected to the fourth bonding pad, wherein, in a cross-sectional view of the semiconductor device, there is no wiring constituting the second circuit in one layer just below the uppermost layer of the wiring layers in regions where the first bonding pad and the second bonding pad are formed, wherein, in a cross-sectional view of the semiconductor device, there is a wiring constituting the second circuit in one layer just below the uppermost layer of the wiring layers in regions where the third to sixth bonding pad are formed, providing a package including a first inner wiring and a second inner wiring; coupling the third and fifth bonding pads by the first inner wiring; and coupling the fourth and sixth bonding pads by the second inner wiring.

In this way, the power supply or ground (GND) can be impedance-reduced. Other features are described in detail below.

According to the above-described embodiment, it is possible to provide a semiconductor device and a semiconductor device manufacturing method capable of achieving both high integration in a semiconductor chip and improvement in I/O capability and ESD resistance.

### BRIEF DESCRIPTION OF THE DRAWINGS

FIG. 1 is a plan view illustrating a configuration of a semiconductor device according to a first embodiment.

FIG. 2 is a diagram schematically illustrating a cross-sectional structure of a bonding pad.

FIG. 3 is a diagram illustrating a positional relationship between a bonding pad and a probe.

FIG. 4 is a diagram schematically illustrating a cross-sectional structure of a bonding pad.

FIG. 5 is a plan view illustrating a configuration of a semiconductor device according to a second embodiment.

FIG. 6 is a plan view illustrating a configuration of a semiconductor device according to the second embodiment.

FIG. 7 is a plan view illustrating a configuration of a semiconductor device according to a third embodiment.

FIG. 8 is a diagram schematically illustrating a cross-sectional structure of a bonding pad.

FIG. 9 is a diagram schematically illustrating a cross-sectional structure of a semiconductor device.

FIG. 10 is a cross-sectional view of the semiconductor chip in the broken line II-II shown in FIG. 1.

FIG. 11 is a diagram for describing a method of manufacturing a semiconductor device according to a fourth embodiment.

### DETAILED DESCRIPTION

### First embodiment

Hereinafter, the present embodiment will be described with reference to the drawings. In the present embodiment, the state of “connecting” includes the case of “electrically connecting”.

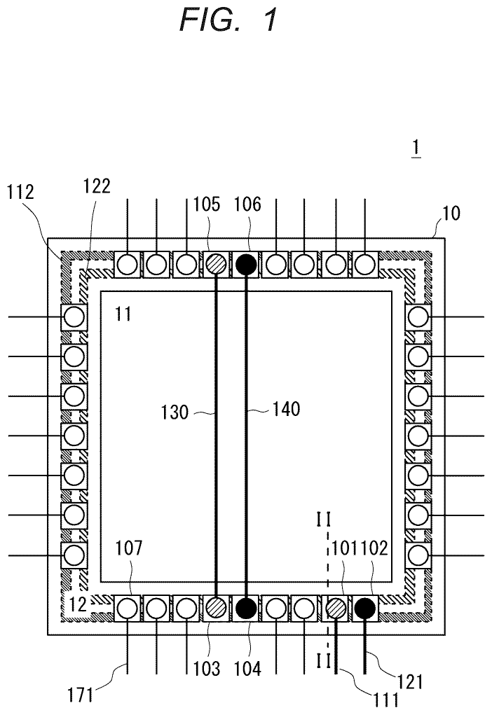

FIG. 1 is a plan view illustrating an example of a semiconductor device 1 according to the present disclosure. The semiconductor device 1 includes a semiconductor chip 10. The semiconductor chip 10 includes a first circuit region 11, a second circuit region 12, and a plurality of bonding pads 101 to 106.

The first circuit region 11 is a region in which a memory circuit, a logic circuit, an analog circuit, and the like are formed. The second circuit area 12 is arranged in a frame shape so as to surround the first circuit area 11, and is an area in which I/O (input/output) circuits such as an input buffer circuit and an output buffer circuit, a level shifter, and the like are formed.

The bonding pad 101 is connected to a power supply via a wiring 111. The bonding pad 102 is connected to a GND (ground) via a wiring 121. The bonding pad 103 is connected to the bonding pad 101 via a power supply wiring 112 provided in the second circuit region 12, and thus can be connected to the power supply. The bonding pad 104 is connected to the bonding pad 102 via GND wiring 122 provided inside the second circuit area 12, and thereby can be connected to the GND.

In the semiconductor device 1 according to the present disclosure, the bonding pad 105 is connected to the bonding pad 103 via the inner wiring 130 disposed above the semiconductor chip 10. Accordingly, the bonding pad 105 can be connected to the power supply via the inner wiring 130, the bonding pad 103, and the bonding pad 101. Similarly, the bonding pad 106 is connected to the bonding pad 104 via the inner wiring 140 disposed above the semiconductor chip 10. Accordingly, the bonding pad 106 can be connected to the GND via the inner wiring 140, the bonding pad 104, and the bonding pad 102.

In the semiconductor device 1 according to the present disclosure, by connecting the bonding pads 103 and 105 using the inner wiring 130, it is possible to suppress the influence of the voltage drop rather than the supply of the power by only the power supply wiring 112 provided in the second circuit region 12.

Although there is no particular limitation on the arrangement of the bonding pads 101 to 106, in view of the above-described advantages, it is preferable to provide one bonding pad 103 and 104 on the same side as the bonding pads 101 and 102 that are directly connected to the power supply and GND, and to provide the other bonding pad 105 and 106 on the other side.

In the semiconductor device 1 according to the present disclosure, by using the inner wiring 130, it is possible to reduce one terminal connected to the external power supply. Similarly, by using the inner wiring 140, one terminal connected to GND can be reduced. As a result, I/O terminal can be added, and the flexibility of designing is improved.

The semiconductor chip 10 included in the semiconductor device 1 includes a plurality of bonding pads used for input and output in addition to the bonding pads 101 to 106 in the second circuit region 12. Since the plurality of bonding pads used for input and output have the same function, the following description will be given by using the wiring 171 connected to the bonding pad 107 and the bonding pad 107 shown in FIG. 1 as a representative example.

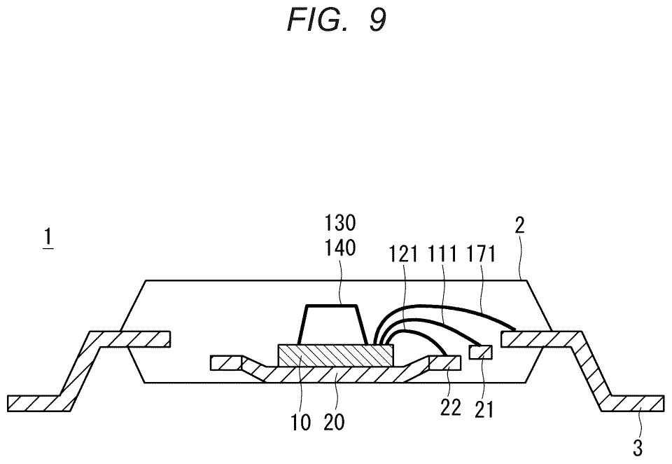

FIG. 9 is a schematic diagram of a cross-sectional structure of the semiconductor device 1 according to the present disclosure. The semiconductor chip 10 included in the semiconductor device 1 is fixed by the die pad 20 and sealed by the resin of the package 2 and the lead of the lead frame 3. The wiring 111 connected to the bonding pad 101 in FIG. 1 is connected to the power supply bar 21 and supplies power to the semiconductor chip 10. The wiring 121 connected to the bonding pad 102 in FIG. 1 is connected to GND ring 22, and the semiconductor chip 10 is grounded.

As illustrated in FIG. 9, the inner wirings 130 and 140 included in the semiconductor device 1 according to the present disclosure are configured to connect bonding pads provided in the semiconductor chip 10 at an upper portion of the semiconductor chip 10.

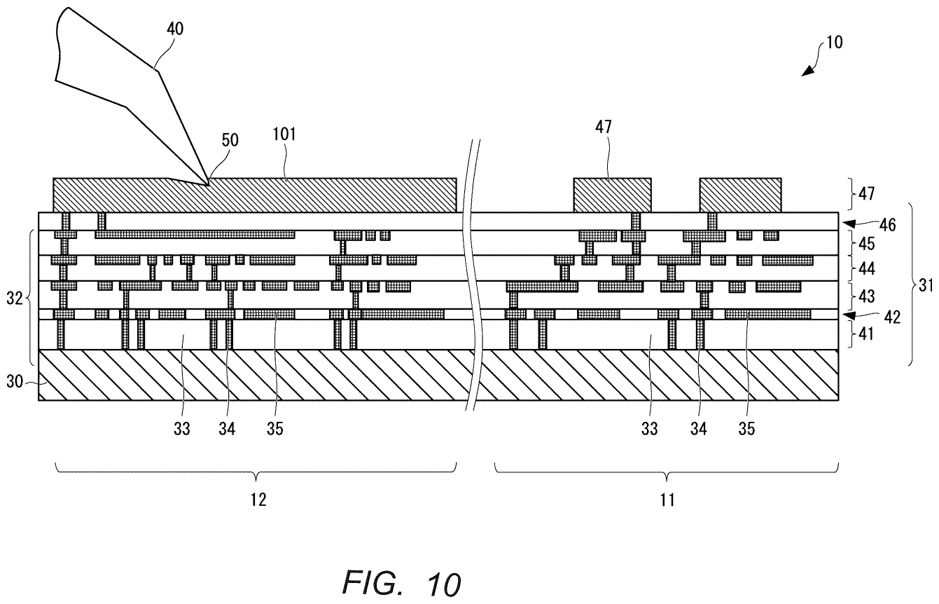

FIG. 10 is a cross-sectional view of the semiconductor chip 10 in the broken line II-II shown in FIG. 1. In the first circuit region 11 and the second circuit region 12, the first circuit 31 and the second circuit 32 are formed on the substrate 30, respectively. Each of the first circuit 31 and the second circuit 32 has a structure in which a plurality of wiring layers 35 are stacked with the interlayer insulating film 33 interposed therebetween, and the wiring layers 35 are connected to each other through the via wiring 34.

Although the number of stacked layers of the first circuit 31 and the second circuit 32 is not particularly limited, a description will be given here of a configuration example in which the first wiring layer 41, the second wiring layer 42, the third wiring layer 43, the fourth wiring layer 44, the fifth wiring layer 45, the sixth wiring layer 46, and the seventh wiring layer 47, which is the uppermost layer, are sequentially stacked from the substrate 30.

In the second circuit region 12, the bonding pad 101 corresponding to the seventh wiring layer 47 is the uppermost layer and is contacted by the probe 40 for inspection, and the probe mark 50 is formed on the bonding pad 101 by physical pressure. In consideration of the influence of the physical pressure applied by the probe 40, it is preferable to adopt a configuration in which the wiring constituting the second circuit 32 is not provided directly under the region where the probe 40 contacts in the sixth wiring layer 46, that is, a configuration in which the wiring constituting the second circuit 32 is not present in the sixth wiring layer 46. By doing so, it is possible to prevent disconnection due to contact of the probe 40. On the other hand, in the first circuit region 11, since the wiring can be provided in the sixth wiring layer 46, the degree of freedom in design is not limited.

In the semiconductor chip 10 according to the present disclosure, the bonding pads 101 and 102 are bonding pads that are in contact with the probe 40.

On the other hand, since the bonding pads 103, 104, 105, and 106 are connected via the inner wirings 130 and 140, the probe 40 is not brought into contact with these bonding pads. By doing so, even in the second circuit region 12, the wiring can be provided directly under the bonding pads 103, 104, 105, and 106, and thus the degree of freedom in design is improved.

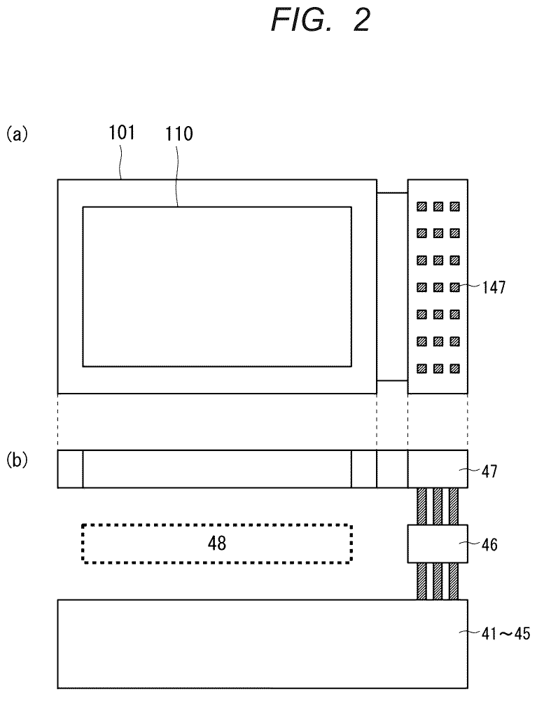

The bonding pads 101 to 107 will be described in detail with reference to FIG. 2. A plan view of the bonding pad 101 included in the semiconductor chip 10 according to the present disclosure is shown in the upper portion (a) of FIG. 2, and a cross-sectional view is shown in the lower portion (b) of FIG. 2. The probe 40 can be connected to the second circuit 32 formed in the second circuit region 12 via the opening 110 of the bonding pad 101 and the pad metal layer 147 formed in the seventh wiring layer 47 in FIG. 10.

Since the bonding pad 101 is a bonding pad in contact with the probe 40, it is preferable that no wiring constituting the second circuit 32 is provided in the region 48 (corresponding to the sixth wiring layer 46) immediately below the region in contact with the probe 40. On the other hand, in order to reduce the physical pressure applied by the probe 40, a dummy via wiring that does not constitute the second circuit 32 or an oxide film having a buffer thickness may be provided in the region 48. The same configuration is applied to the bonding pads 102 and 107, which are bonding pads in contact with the probe 40.

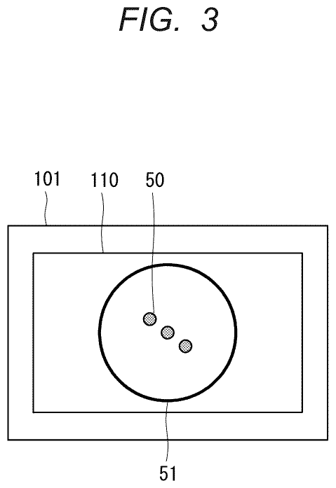

FIG. 3 is a diagram illustrating a positional relationship between a region where the probe 40 contacts and the bonding pad 101. In the semiconductor chip 10 according to the present disclosure, it is preferable that the probe mark 50 formed by the probe 40 contacting the bonding pad 101 and the bonding hole 51 overlap each other.

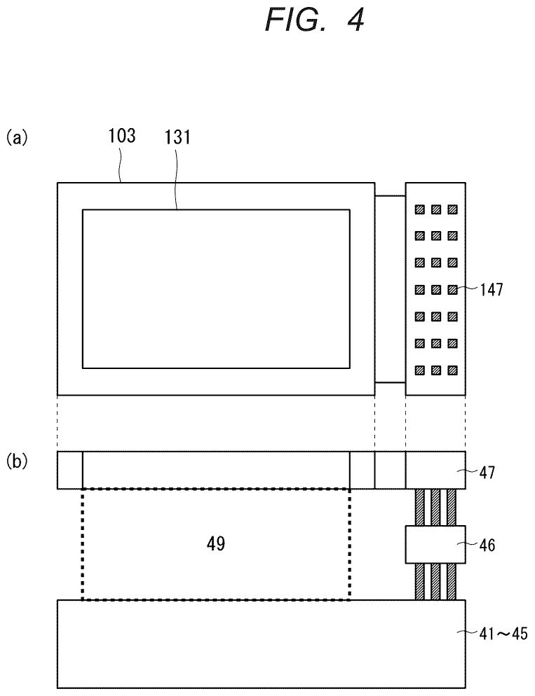

A plan view of the bonding pad 103 is shown in the upper portion (a) of FIG. 4, and a cross-sectional view of it is shown in the lower portion (b) of FIG. 4. The bonding pad 103 is configured such that the probe 40 does not come into contact with it because the inner wiring 130 is connected. Therefore, the wiring constituting the second circuit 32 can also be provided in the region 49 (corresponding to the sixth wiring layer 46) immediately below the opening 131 of the bonding pad 103. In addition, the bonding pads 104, 105, and 106, which are bonding pads to which the inner wirings 130 or 140 are connected, have the same configuration.

By connecting the bonding pads 103 and 105 using the inner wiring 130 as described above, the effect of the voltage drop can be suppressed, the impedance of the power supply and GND can be reduced, and the number of the power supply terminal and GND terminal can be reduced. In addition, since the wiring constituting the second circuit 32 is not provided in the region 48 immediately below the region where the bonding pads 101, 102, and 107 are formed, disconnection due to contact with the probe 40 can be prevented. Further, since the wiring constituting the second circuit 32 can be provided in the region 49 immediately below the region where the bonding pads 103 to 106 are formed, the degree of freedom in design is improved.

### Second Embodiment

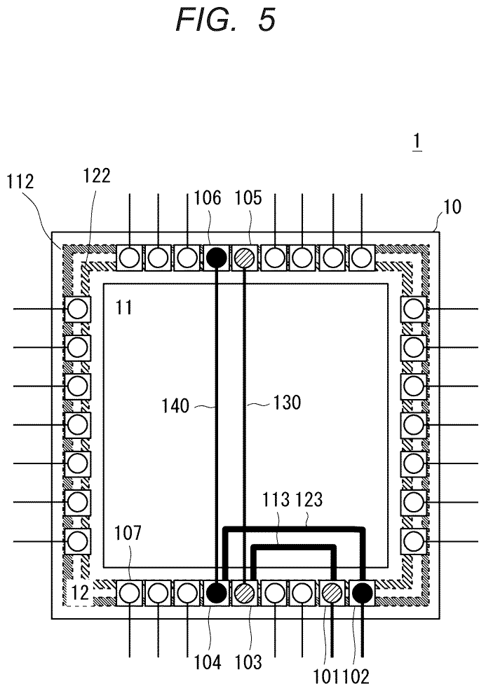

This embodiment describes a semiconductor device in which the first embodiment is extended. FIG. 5 is a plan view illustrating an example of the semiconductor device 1 according to the present embodiment. Components that overlap with FIG. 1 are omitted in order to avoid repeated description.

The semiconductor device 1 according to the present embodiment further includes a power supply wiring 113 and a GND wiring 123 in addition to the configuration of the semiconductor device 1 according to the first embodiment, that is, the configuration of the semiconductor device 1 shown in FIG. 1. The power supply wiring 113 and GND wiring 123 are formed in the seventh wiring layer 47 in FIG. 10, and overlap not only the second circuit region 12 but also the first circuit region 11.

The bonding pads 101 and 103 are connected by the power supply wiring 113, and the bonding pads 103 and 105 are connected by the inner wiring 130. The bonding pads 102 and 104 are connected by GND wiring 123, and the bonding pads 104 and 106 are connected by the inner wiring 140. As a result, the current value can be increased, so that the width of the product specification can be increased.

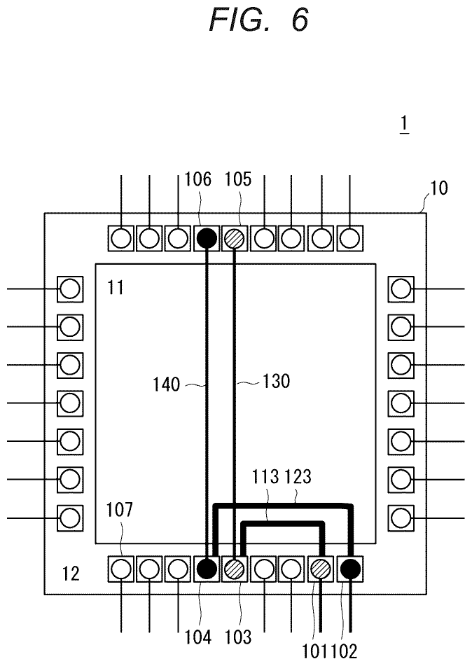

Further, in the semiconductor device 1 according to the present embodiment, the power supply wiring 113 and GND wiring 123 and the inner wirings 130 and 140 are provided, so that power can be easily supplied to the bonding pads 105 and 106. Therefore, the power supply wiring 112 and GND wiring 122 in the second circuit area 12 can be omitted, and a semiconductor chip having a space-saving configuration can be formed (see FIG. 6).

### Third Embodiment

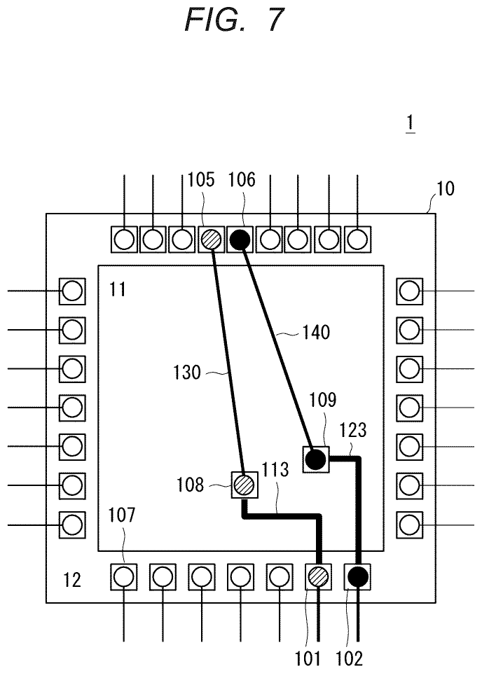

The present embodiment describes a modification example of the semiconductor devices of the first and second embodiments. FIG. 7 is a plan view illustrating an example of the semiconductor device 1 according to this embodiment. For components that overlap with FIG. 1, for example, the power supply wiring 112 and GND wiring 122 provided in the second circuit area 12 are omitted in order to avoid repeated explanation.

In the semiconductor device 1 according to the present embodiment, in the first embodiment, that is, in the configuration of the semiconductor device 1 shown in FIG. 1, the bonding pads 103 and 104 provided in the second circuit region 12 are omitted, and the bonding pads 108 and 109 are provided in the first circuit region 11. In addition, similar to the second embodiment, that is, similar to the semiconductor device 1 shown in FIG. 5, the power supply wiring 113 and GND wiring 123 that are formed in the seventh wiring layer 47 in FIG. 10 and that overlap not only the second circuit region 12 but also the first circuit region 11 are provided.

Note that the bonding pads 108 and 109 are preferably formed in the seventh wiring layers 47 in FIG. 10, similarly to the power supply wiring 113 and GND wiring 123. In addition, it is preferable that the bonding pads 108 and 109 provided in the first circuit region 11 are not provided in a region where an analog circuit is formed in order to avoid a change in characteristics.

The bonding pad 108 is connected to the bonding pad 101 by the power supply wiring 113, and is connected to the bonding pad 105 by the inner wiring 130. The bonding pad 109 is connected to the bonding pad 102 by GND wiring 123, and is connected to the bonding pad 106 by the inner wiring 140. Since a space is created for the bonding pads 103 and 104 that were provided in the second circuit region 12, it becomes possible to add I/O terminal specifications.

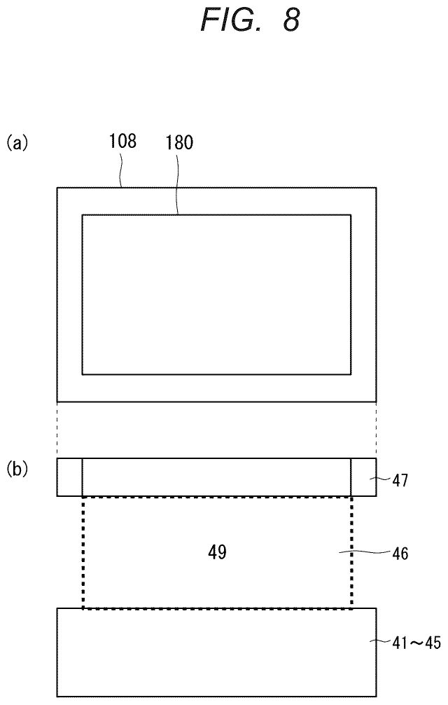

An upper portion (a) of FIG. 8 is a plan view of the bonding pad 108 provided in the first circuit region 11, and a lower portion (b) of FIG. 8 is a cross-sectional view of it. The bonding pad 108 is configured such that the probe 40 does not come into contact with it because the inner wiring 130 is connected. Therefore, the wiring constituting the first circuit 31 can also be provided in the region 49 (corresponding to the sixth wiring layer 46) immediately below the opening 180 of the bonding pad 108. The bonding pad 109, which is a bonding pad connected to the inner wiring 140 and provided in the first circuit region 11, has the same configuration.

### Fourth Embodiment

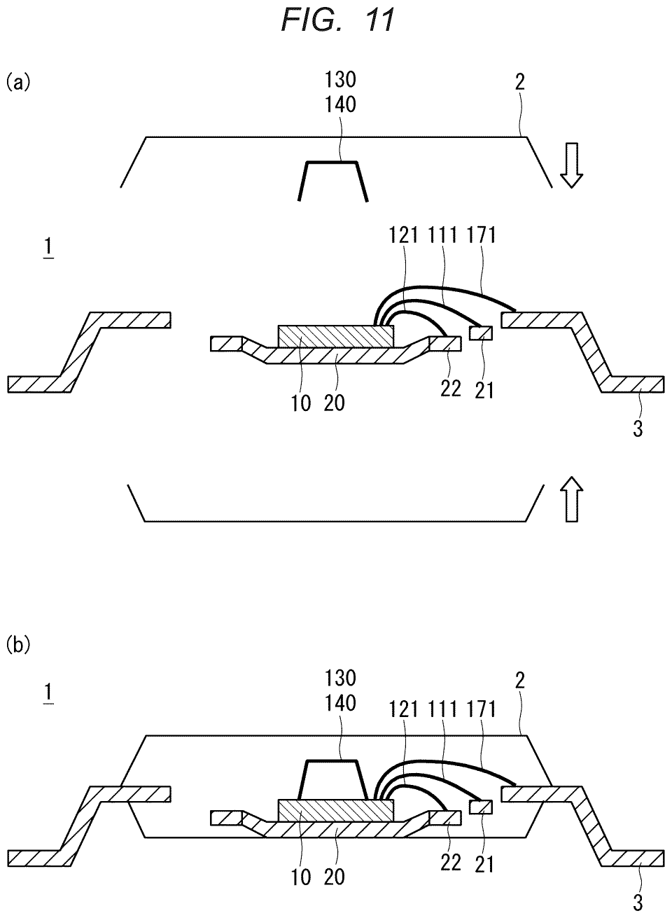

In the present embodiment, a method of manufacturing the semiconductor device 1 according to the first to third embodiments will be described with reference to FIG. 11. First, the semiconductor device 1 in a state prior to the formation of the inner wirings 130 and 140, that is, the semiconductor device 1 in a state in which the semiconductor chip 10 is fixed to the die pad and the wirings 111, 121, and 171 are connected to the leads of the power supply bar 21, GND ring 22, and the lead frame 3, respectively, is prepared.

Next, the package 2 including the inner wirings 130 and 140 is mounted on the semiconductor device 1 using resin. As a result, a plurality of bonding pads in the semiconductor chip 10 are connected by the inner wirings 130 and 140, and the semiconductor device 1 is manufactured.

In this way, it is possible to provide a semiconductor device manufacturing process capable of achieving both high integration in a semiconductor chip and improvement in I/O capability and ESD resistance.

Although the invention made by the present inventors has been described in detail based on the embodiments, it is needless to say that the present invention is not limited to the above-described embodiments and can be variously modified without departing from the gist thereof.

What is claimed is:

1. A semiconductor device comprising:
a semiconductor chip comprising:
a substrate;
a first circuit region on the substrate;
a second circuit region disposed on the substrate and surrounding the first circuit region in a plan view of the semiconductor device; and
a plurality of bonding pads,
wherein the substrate includes a plurality of wiring layers,
wherein the first circuit region is provided with a first circuit constituted by the wiring layers,
wherein the second circuit region is provided with a second circuit constituted by the wiring layers,
wherein the plurality of bonding pads is formed in the second circuit region, and is constituted by an uppermost layer of the wiring layers,
wherein the plurality of bonding pads comprises:
a first bonding pad and a third bonding pad connected to a power supply outside the semiconductor chip;
a second bonding pad and a fourth bonding pad connected to a ground;
a fifth bonding pad connected to the third bonding pad via a first inner wiring; and
a sixth bonding pad connected to the fourth bonding pad via a second inner wiring,
wherein, in a cross-sectional view of the semiconductor device, there is no wiring constituting the second circuit in one layer just below the uppermost layer of the wiring layers in regions where the first bonding pad and the second bonding pad are formed, and
wherein, in a cross-sectional view of the semiconductor device, there is a wiring constituting the second circuit in one layer just below the uppermost layer of the wiring layers in regions where the third to sixth bonding pad are formed.

2. The semiconductor device according to claim 1, wherein the first circuit is a memory circuit or a logic circuit, and wherein the second circuit is an input/output circuit or a level shifter.

3. The semiconductor device according to claim 2, wherein in a cross-sectional view of the semiconductor device, there is a wiring constituting the first circuit in the one layer just below the uppermost layer of the wiring layers.

4. The semiconductor device according to claim 1,
wherein the semiconductor chip further comprises a power supply wiring and a ground wiring formed on the uppermost layer of the wiring layers,
wherein the power supply wiring and the ground wiring overlaps the first circuit region and the second circuit region,
wherein the first bonding pad and the third bonding pad are connected to each other by the power supply wiring, and
wherein the second bonding pad and the fourth bonding pad are connected to each other by the ground wiring.

5. A semiconductor device comprising:
a semiconductor chip comprising:
a substrate;
a first circuit region on the substrate;
a second circuit region disposed on the substrate and surrounding the first circuit region in a plan view of the semiconductor device; and
a plurality of bonding pads,
wherein the substrate includes a plurality of wiring layers,
wherein the first circuit region is provided with a first circuit constituted by the wiring layers,
wherein the second circuit region is provided with a second circuit constituted by the wiring layers,
wherein the plurality of bonding pads is constituted by an uppermost layer of the wiring layers,
wherein the plurality of bonding pads comprises:
a first bonding pad formed in the second circuit region and connected to a power supply outside the semiconductor chip;
a second bonding pad formed in the second circuit region and connected to a ground;
a third bonding pad formed in the first circuit region and connected to the power supply;
a fourth bonding pad formed in the first circuit region and connected to the ground;
a fifth bonding pad formed in the second circuit region and connected to the third bonding pad via a first inner wiring; and
a sixth bonding pad formed in the second circuit region and connected to the fourth bonding pad via a second inner wiring,
wherein, in a cross-sectional view of the semiconductor device, there is no wiring constituting the second circuit in one layer just below the uppermost layer of the wiring layers in regions where the first bonding pad and the second bonding pad are formed,
wherein, in a cross-sectional view of the semiconductor device, there is no wiring constituting the first circuit in one layer just below the uppermost layer of the wiring layers in regions where the third bonding pad and the fourth bonding pad are formed, and
wherein, in a cross-sectional view of the semiconductor device, there is a wiring constituting the second circuit in one layer just below the uppermost layer of the wiring layers in regions where the fifth bonding pad and sixth bonding pad are formed.

6. The semiconductor device according to claim 5, wherein the first circuit is a memory circuit or a logic circuit, and wherein the second circuit is an input/output circuit or a level shifter.

7. The semiconductor device according to claim 6, wherein in a cross-sectional view of the semiconductor device, there is a wiring constituting the first circuit in the one layer just below the uppermost layer of the wiring layers.
